(19) United States
(12) Patent Application Publication
(10) Pub. No.: US 2006/0118931 A1
(43) Pub. Date: Jun. 8, 2006

(54) Assembly structure and method for embedded passive device

(76) Inventors: Kwun-Yao Ho, Hsin-Tien City (TW); Moriss Kung, Hsin-Tien City (TW)

Correspondence Address: J C PATENTS, INC., 4 VENTURE, SUITE 250, IRVINE, CA, 92618, US

(21) Appl. No.: 11/133,646

(22) Filed: May 20, 2005

(30) Foreign Application Priority Data
Dec. 3, 2004 (TW) 93137323

(51) Int. Cl. H01L 23/02

(52) U.S. Cl. 257/678

(57) ABSTRACT

An assembly structure for an embedded passive device is provided, including at least one passive device embedded in a through hole of a core layer in a circuit substrate. The embedded passive device comprises plural electrodes, which electrically connect through the top side and the bottom side of the core layer. Because the vertically embedded passive device does not occupy the layout area of internal circuit of the circuit substrate, the layout area of the circuit substrate can be increased, the signal transmission route can be reduced, and the performance of signal transmission can be enhanced.

### CROSS-REFERENCE TO RELATED APPLICATION

This application claims the priority benefit of Taiwan application serial no. 93137323, filed on Dec. 3, 2004. All disclosure of the Taiwan application is incorporated herein by reference.

### BACKGROUND OF THE INVENTION

1. Field of the Invention

The present invention relates to an assembly structure of an embedded passive device, and more particular to an assembly structure and a process to vertically dispose an embedded passive device in a circuit substrate.

2. Description of the Related Art

Generally, a circuit substrate comprises multiple patterned circuit layers and dielectric layers which are alternatively stacked over each other. Wherein, the patterned circuit layers are made of, for example, copper foils which are defined by a photolithographic process. The dielectric layer is disposed between the patterned circuit layers to isolate the patterned circuit layers. In addition, the stacked patterned circuit layers are connected to each other through plating through holes (PTHs) or conductive vias. Wherein, the through holes are formed by a mechanical drilling method, and then an electroplating layer is formed on the sidewall of the through holes by a copper electroplating method. A dielectric material is then filled in the through hole, serving as PTHs for electrically connecting the circuit layers, the power plane and ground plane. A variety of electronic devices, such as active devices and passive devices, can be disposed on the surface of the circuit substrate. With the design of the internal circuit, the electrical signal propagation can be performed.

The passive device can be, for example, a capacitor, a resistor, or an inductor which is disposed on the surface of the circuit substrate by a surface mounting technology (SMT). In addition, the passive device can also be embedded in the internal of the circuit substrate to increase the surface layout of the substrate.

FIG. 1 is a partial schematic drawing of a conventional circuit substrate with an embedded passive device. The circuit substrate 100 comprises a power plane 110 and a ground plane 120. The power plane 110 and the ground plane 120 electrically connect with a patterned circuit layer 130 through conductive vias 112 and 122, respectively. Wherein, the power plane 110 and the ground plane 120 are coplanar. Electrodes 104 and 106 of the embedded passive device 102 are connected between the power plane 110 and the ground plane 120 by a solder paste 108. In the prior art, the passive device 102 is horizontally embedded in the circuit substrate 100. Note that once the number of the passive devices 102 is increased, the internal layout area for the passive devices 102 is reduced. Moreover, the locations of the conductive vias 112 and 122 must be far away from the top and bottom surfaces of the passive device 102. Therefore, the signal transmission route is increased such that the electrical signal propagation declines. Furthermore, the power plane 110 and the ground plane 120 electrically connected to the electrodes of the passive component are disposed in the same conductive layer. It is a limitation and an inconvenience in the circuit layout.

### SUMMARY OF THE INVENTION

Accordingly, the present invention is directed to an assembly structure and a process for an embedded passive device. By improving the method of disposing the embedded passive device, the internal layout area of the circuit substrate is increased and the data transmission route is reduced.

The present invention discloses an assembly structure of an embedded passive device. The structure comprises a circuit substrate and at least one passive device. The circuit substrate comprises a multi-layered structure. The multi-layered structure comprises a core layer, a first conductive layer and a second conductive layer. The core layer comprises at least one through hole to dispose a passive device. The passive device vertically connects a first conductive layer and a second conductive layer through the first conductive vias and the second conductive vias, respectively. The passive device is covered by a filling material. A plurality of electrodes of the passive device are exposed outside the filling material, wherein at least one of the electrodes is correspondingly connected to the first conductive via, and at least one of the electrodes is correspondingly connected to the second conductive via.

The present invention provides an assembly method for an embedded passive device. The assembly method is adapted for a circuit substrate. The assembly method for the embedded passive device comprises the following steps: First, at least one through hole is pre-formed in a core layer of the circuit substrate. A passive device is disposed in the through hole, and electrodes of the passive device are correspondingly located on a top and a bottom of the through hole. A dielectric material is filled in the through hole covering the passive device. A portion of the dielectric material is removed to expose electrodes of the passive device in a plurality of concaves of the dielectric material. A first conductive via and a second conductive via are formed to cover the concaves, respectively. The first conductive via electrically connects to one electrode of the passive device and the second conductive via electrically connects to the other electrode of the passive device.

The present invention uses a method and structure to vertically dispose the passive device so that the passive device can be disposed in the core layer which has available space. Then, a filling material covers the passive device to fix the passive device in the through hole of the core layer. Accordingly, for the availability of the circuit substrate area, the embedded passive device does not occupy the layout area of the internal circuit of the substrate. In addition, by using the present substrate manufacturing process, the assembly process for the vertically embedded passive device can be added thereon to enhance convenience and efficiency. Without using the Sn/Pb solder paste, the environmental pollution can be substantially reduced.

The above and other features of the present invention will be better understood from the following detailed description of the preferred embodiments of the invention that is provided in communication with the accompanying drawings.

### BRIEF DESCRIPTION OF THE DRAWINGS

FIG. 1 is a partial schematic drawing of a conventional circuit substrate with an embedded passive device.

FIGS. 2-8 are schematic drawings showing progression of an assembly method for an embedded passive device according to an embodiment of the present invention.

FIG. 9 is a schematic cross-sectional view of a chip package structure according to an embodiment of the present invention.

FIG. 10 is a schematic cross-sectional view of a circuit substrate according to another embodiment of the present invention.

FIG. 11 is a schematic cross-sectional view of a circuit substrate according to the third embodiment of the present invention.

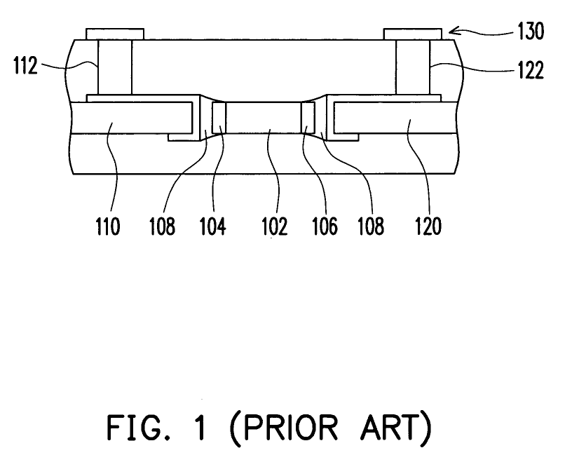

### DESCRIPTION OF SOME EMBODIMENTS

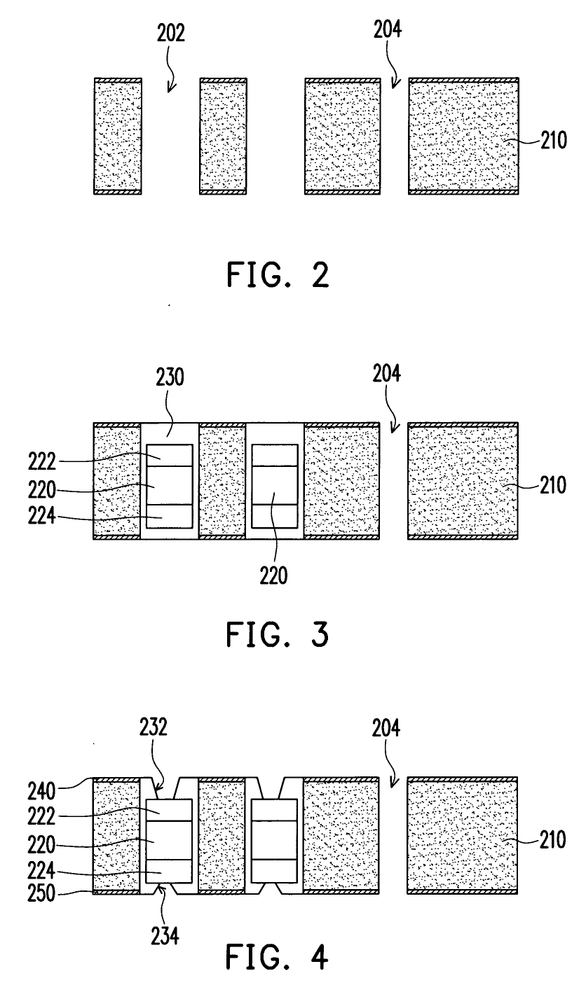

FIGS. 2-8 are schematic drawings showing progression of an assembly method for an embedded passive device according to an embodiment of the present invention. The assembly process for the embedded passive device is adapted for a circuit substrate. The assembly process comprises the following steps: S110, S120, S130, S140 and S150. First, at least one through hole is pre-formed in a core layer of the circuit substrate in step S110. In step S120, a passive device is disposed in the through hole, and the electrodes of the passive device are correspondingly located on the top and bottom of the through hole. In step S130, a dielectric material is filled in the through hole to cover the passive device. A portion of the dielectric material is removed to expose the electrodes of the passive device in the plural concaves of the dielectric layer. In step S140, a first conductive via and a second conductive via are formed to cover the concaves, respectively. The first conductive layer and the second conductive layer are electrically and separately connected with the electrodes of the passive device.

Referring to FIG. 2, in step S110, a plural through holes 202 and 204 are formed in the core layer 210 by a mechanical drilling method, a laser drilling method, or a plasma etching process, for example. The core layer 210 can be, for example, an insulating core layer, made of glass epoxy resin FR-4 or FR-5, bismaleimide-triazine (BT) or epoxy resin, for example.

Referring to FIGS. 3 and 4, in step S120, the passive device 220 can be, for example, a capacitor, a resistor, an inductor, or an integrated passive module which is correspondingly disposed in a through hole 202 of the core layer 210. Two electrodes 222 and 224 of the passive device 220 are correspondingly located on the top or the bottom of the through hole 202, respectively. In step S130, a filling material or a dielectric material 230 is filled in the through hole 202 embedded with the passive device 220, covering the passive device 220. Wherein, the dielectric material 230 can be, for example, photo-sensitive resin, thermoplastic resin, or other thermosetting polymers. A portion of the dielectric material 230 is removed by a photolithographic process included an exposure and a development step, by a laser drilling method, or by a plasma etching process. The electrodes 222 and 224 of the passive device 220 are exposed by the concaves 232 and 234 in the dielectric material 230, respectively. It should be noted that in this embodiment, the dimension of the through hole 202 can only contain a single passive device or multiple vertically connected passive devices. The through hole 204 without the passive device 220 can be smaller or equal to the size of the through hole 202 with the passive device 220. The through hole 204 can serve as a conductive through hole to connect two patterned circuit layers in a subsequent process. Moreover, an electroplating layer 206 can be formed on the sidewall of the through hole 204.

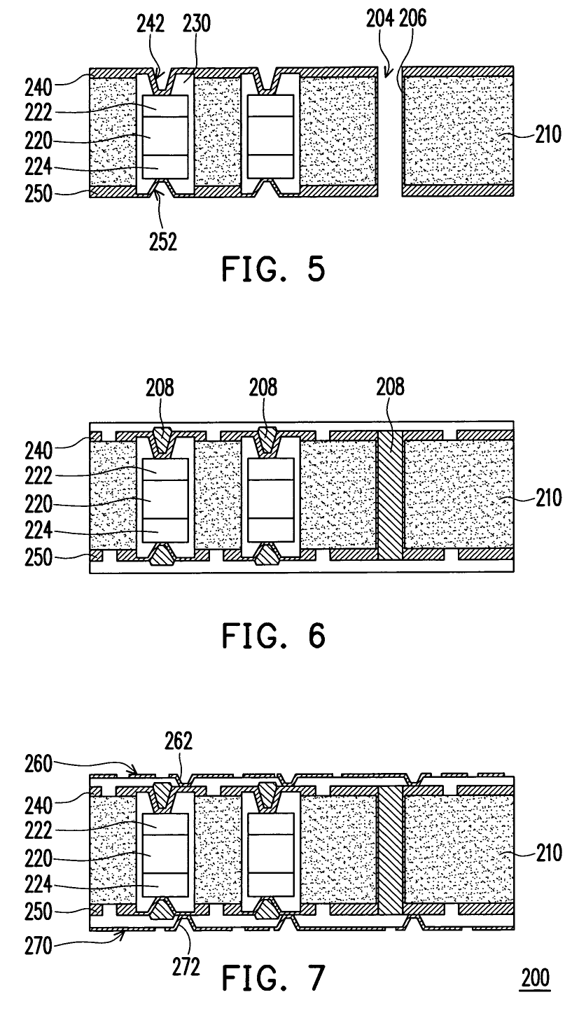

Referring to FIG. 5, in step S130, the first conductive layer 240 and the second conductive layer 250 can be, for example, either a power plane or a ground plane. The first conductive layer 240 and the second conductive layer 250 cover the first surface and the second surface of the core layer 210, respectively. In addition, in the process of forming the electroplating layer 206 on the sidewall of the through hole 204, the electroplating conductive metal can also be formed in concaves 232 and 234 of the dielectric material 230 to form two conductive vias 242 and 252 concaved in the through hole 202. The electrodes 222 and 224 of the passive device 220 electrically connect with the first conductive layer 240 and the second conductive layer 250 through the conductive vias 242 and 252, respectively.

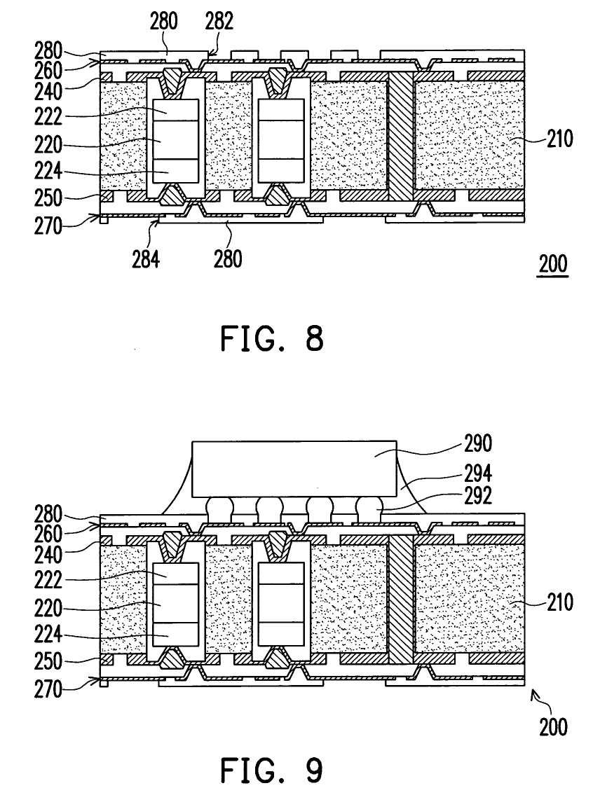

Referring to FIG. 6, after the assembly process of embedding the passive device 220, a dielectric material 208 can be further filled in the through hole 204 and in the conductive vias 242, 252. The conductive vias 242 and 252 can be formed, for example, by electroplating copper, for example, to partially or fully fill the concaves 232 and 234. Referring to FIGS. 7 and 8, the patterned circuit layers 260 and 270 of the circuit substrate 200 are sequentially formed. The outer patterned circuit layers 260 and 270, and the reference planes 240 and 250 (i.e., the first and the second conductive layers), are separated by a dielectric layer, respectively. The outer patterned circuit layers 260 and 270 also electrically connect with the reference planes 240 and 250 through plural conductive vias 262 and 272, respectively. In addition, in FIG. 8, a solder mask layer 280 can further be formed, covering the surfaces of the outer patterned circuit layers 260 and 270. The solder mask layer 280 comprises plural openings 282 and 284, which defines the connection positions of the outer patterned circuit layers 260 and 270 to serve as the top contacts and bottom contacts of the circuit substrate 200 to electrically connect with external electronic apparatus or device, such as a chip or a printed circuit board.

FIG. 9 is a schematic cross-sectional view of a chip package structure according to an embodiment of the present invention. By using the circuit substrate 200 formed by the assembly method for the embedded passive device in the present invention, a flip chip 290 or a wire-bonding type of chip can be, for example, disposed over the top surface of the circuit substrate 200. The circuit substrate 200 is electrically connected with the flip chip 290 through bumps 292. Moreover, a underfill 294 covers the bumps 292. Wherein, the passive device 220 can be, for example, disposed in the circuit substrate 200 right under the flip chip 290 and vertically disposed in the core layer 210. Accordingly, signals transmitted from the flip chip 290 can vertically conduct between the electrodes 222 and 224 of the passive device 220, and the signal transmission route is reduced. In addition, the passive device 220 is disposed in the core layer 210 without using the layout surface of the circuit substrate 200. Moreover, the passive device is covered by the filling material 230. Without using solder pastes to connect the electrodes 222 and 224, the reflow process for solder pastes can be saved. In addition, compared with the horizontal embedded passive device in the prior art, the vertical embedded passive device of the present invention can overcome the obstacle of the conventional technology and the process can be precisely controlled. Even if passive devices are increased, they can be embedded in the circuit substrate and formed in the same process. Accordingly, the present invention provides an easy and convenient process and structure.

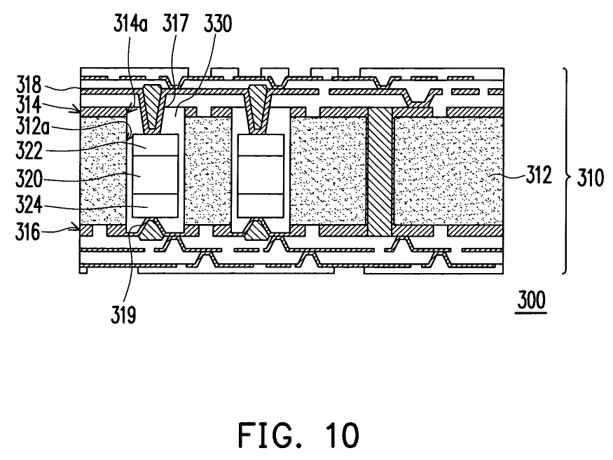

FIG. 10 is a schematic cross-sectional view of a circuit substrate according to another embodiment of the present invention. The circuit substrate 300 comprises a multi-layered structure 310 and two passive devices 320. The multi-layered structure 310 comprises, for example, a core layer 312, a first reference plane 314, a second reference plane 316, and a third reference plane 318. The core layer 312 is made of the dielectric material and may further comprise multiple conductive layers inside the dielectric material. The first reference plane 314 and the second reference plane 316 are disposed over the top surface and the bottom surface of the core layer 312, respectively. Furthermore, there are more conductive layers laminated on the core layer 312, such as the third reference plane 318 or other signal circuits. In other words, the multi-layered structure 310 has multiple conductive layers to satisfy the layout specifications. The core layer 312 comprises at least one through hole 312a between the first reference plane 314 and the second reference plane 316. Wherein, the third reference plane 318 is, for example, adjacent to the first reference plane 314. These reference planes 314, 316 and 318 comprise at least two conductive vias 317 and 319, which are formed in the through hole 312a. In addition, the passive device 320 is disposed in the through hole 312a and covered by a filling material 330. Two electrodes 322 and 324 of the passive device 320 are correspondingly connected to the conductive vias 317 and 319 of the reference planes 314, 316 and 318. In this embodiment, the first reference plane 314, the second reference plane 316, and the third reference plane 318 can be, for example, a power plane or a ground plane. The first reference plane 314 comprises a cutting hole 314a corresponding to the through hole 312a so that the conductive via 317 of the third reference plane 318 electrically connects with the electrode 322 of the passive device 320 through the cutting hole 314a. The present invention, however, is not limited to this embodiment. In some embodiments, the method of disposing the conductive vias can be modified or the conductive vias can be spared.

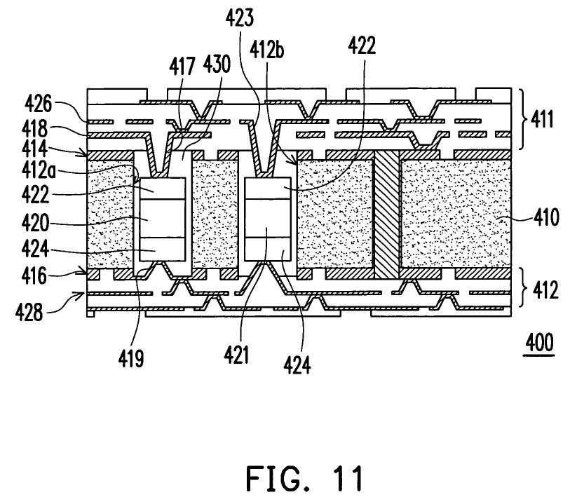

FIG. 11 is a schematic cross-sectional view of a circuit substrate according to the third embodiment of the present invention. The circuit substrate 400 comprises a core layer 410, a first circuit structure 411, and a second circuit structure 412. The first circuit structure 411 which has a plurality of conductive layers is disposed on a first side of the core layer 410. Similarly, the second circuit structure 412 which also has a plurality of conductive layers is disposed on a second side of the core layer 410. The core layer 410 further comprises at least two through holes 412a between the first surface and the second surface. The first reference plane 414 of the first circuit structure 411 is disposed on the first surface of the core layer, and the second reference plane 416 of the second circuit structure 412 is disposed on the second surface of the core layer. The first passive device 420 is disposed in one through hole 412a and covered by a dielectric material 430. Two electrode 422 and 424 of the first passive device 420 are correspondingly connected to the third reference plane 418 of the first circuit structure 411 through the first conductive via 417 and to the second reference plane 416 through a second conductive via 419. Similarly, the second passive device 421 is disposed in another through hole 412b and covered by the dielectric material 430. The electrode 422 of the second passive device 421 is electrically connected to a patterned circuit layer 426 in the first circuit structure 411 through the conductive via 423. The electrode 424 of the second passive device 421 is electrically connected to a fourth reference plane 428 in the second circuit structure 412. In other words, one electrode of the passive device connects to any conductive layer in the first side of the core layer through the first conductive via 417, and the other electrode of the passive device connects to any conductive layer in the second side of the core layer through the second conductive via 419. Thus the passive devices in the through holes are not limited to connect to the same conductive layers. Furthermore, the passive device could connect with two reference planes, connect with one reference plane and one signal circuit in a patterned circuit layer, or connect with two signal circuits of two different patterned circuit layers. The reference planes could be a power plane or a ground plane. Thus the present invention provides a flexible structure for the different circuit needs.

Accordingly, the circuit substrate and the chip package structure of the present invention use the vertically embedded method so that the passive device is disposed in the core layer. By covering the passive device with a filling material, the passive device is fixed in the through hole of the core layer. As a result, for the circuit substrate, the vertically embedded passive device does not occupy the layout area of the internal circuit of the circuit substrate. By adding the assembly process for the vertically embedded passive device in the present substrate fabricating process, the present invention can enhance convenience and efficiency.

Accordingly, the circuit substrate, the chip package structure, and the assembly process for the embedded passive device have at least the following advantages:

(1) The vertically embedded passive device does not occupy the layout area of the internal circuit of the circuit substrate. Thus, the internal layout area of the circuit substrate can be effectively increased.

(2) The structure and method for vertically embedding the passive device can be added to the current substrate fabricating process to enhance convenience and efficiency.

(3) Compared with the conventional circuit substrate where the passive device is disposed outside, the circuit substrate of the present invention provides more area for layout of the outer patterned circuit layer.

(4) By using the circuit substrate with the vertically embedded passive device and the chip package structure thereof, the signal transmission route is reduced and the efficiency of the signal transmission can be improved.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention. What is claimed is:

1. An assembly structure of an embedded passive device, the structure comprising:
a circuit substrate, comprising a multi-layered structure having a plurality of conductive layers, the multi-layered structure comprising a core layer, a plurality of first conductive layers disposed on a first side of the core layer, and a plurality of second conductive layers disposed on a second side of the core layer, the core layer comprising at least one through hole between the first conductive layer and the second conductive layer;
at least one first passive device, disposed in the through hole and covered with a filling material, having a first electrode and a second electrode exposed outside the filling material;
at least a first conductive via, disposed on the first side of the core layer, and
at least a second conductive via, disposed on the second side of the core layer, wherein the first electrode of the first passive device electrically connected to one of the first conductive layers through the first conductive via and the second electrode of the first passive device electrically connected to one of the second conductive layers through the second conductive via.

2. The assembly structure of an embedded passive device of claim 1, wherein the first conductive layer is a power plane, a ground plane, or a signal circuit, and the second conductive layer is a power plane, a ground plane, or a signal circuit.

3. The assembly structure of an embedded passive device of claim 1, wherein the filling material is a dielectric material.

4. The assembly structure of an embedded passive device of claim 1, wherein the passive device is a resistor, a capacitor, an inductor or an integrated passive module.

5. The assembly structure of an embedded passive device of claim 1, wherein an outer conductive layer of the multi-layered structure is a patterned circuit layer, and the core layer further comprises at least one conductive through hole, which is electrically connected to the patterned circuit layer.

6. The assembly structure of an embedded passive device of claim 5, further comprising a solder mask layer covering the patterned circuit layer, the solder mask layer comprising a plurality of openings exposing connection points of the patterned circuit layer.

7. The assembly structure of an embedded passive device of claim 1, further comprising at least one second passive device disposed in another through hole of the core layer, wherein one electrode of the second passive device electrically connected to another first conductive layer of the multi-layered structure.

8. The assembly structure of an embedded passive device of claim 1, wherein the first electrode of the first passive device electrically connects to the first conductive layer which is disposed on a first surface of the core layer.

9. The assembly structure of an embedded passive device of claim 1, wherein the second electrode of the first passive device electrically connects to the second conductive layer which is disposed on a second surface of the core layer.

10. A chip package structure, comprising:
a circuit substrate comprising a core layer with a plurality of through holes, a plurality of first conductive layers disposed in a first side of the core layer, a plurality of second conductive layers disposed in a second side of the core layer, and at least one first passive device disposed in one of the through holes, the first passive device comprising two electrodes, which respectively connect to one of the first conductive layers through a first conductive via and to one of the second conductive layers through a second conductive via; and
a chip disposed on the circuit substrate, and electrically connected to the circuit substrate.

11. The chip package structure of claim 10, wherein the first conductive layer is a power plane, a ground plane, or a signal circuit, and the second conductive layer is a power plane, a ground plane, or a signal circuit.

12. The chip package structure of claim 10, wherein the circuit substrate further comprises a second passive device in another through hole of the core layer having one electrode electrically connected to another first conductive layer.

13. The chip package structure of claim 10, further comprising a filling material covering the passive device, the filling material comprising a plurality of concaves correspondingly exposing the electrodes of the passive device.

14. The chip package structure of claim 10, wherein the passive device is a resistor, a capacitor, an inductor, or an integrated passive module.

15. The chip package structure of claim 10, wherein an outer conductive layer of the multi-layered structure is a patterned circuit layer, and the core layer further comprises at least one conductive through hole, which is electrically connected to the patterned circuit layer.

16. The chip package structure of claim 15, further comprising a solder mask layer covering the patterned circuit layer, the solder mask layer comprising a plurality of openings exposing connection points of the patterned circuit layer.

17. An assembly method for an embedded passive device, the assembly method adapted for a circuit substrate, the assembly method comprising:
pre-forming at least one through hole in a core layer of the circuit substrate;
disposing a passive device in the through hole, with a first electrode and a second electrode of the passive device corresponding to a top and a bottom of the through hole;
filling a dielectric material in the through hole covering the passive device;
removing a portion of the dielectric material to expose electrodes of the passive device out of a plurality of concaves in the dielectric material; and
forming a plurality of first conductive vias to cover the top concaves and forming a plurality of second conductive vias to cover the bottom concaves, one of the first conductive vias electrically connects to the first electrode of the passive device and one of the second conductive vias electrically connects to the second electrode of the passive device.

18. The assembly method for the embedded passive device of claim 17, wherein the through hole is formed by a mechanical drilling method, a laser drilling method, or a plasma etching process.

19. The assembly method for the embedded passive device of claim 17, wherein the top concaves and the bottom concaves are formed by a photolithographic method, a laser drilling method, or a plasma etching process.

20. The assembly method for the embedded passive device of claim 17, wherein the first conductive layer is a power plane, a ground plane, or a signal circuit, and the second conductive layer is a power plane, a ground plane, or a signal circuit.
